(19) United States
(12) Patent Application Publication
(10) Pub. No.: US 2005/0241582 A1
(43) Pub. Date: Nov. 3, 2005

(54) Atmospheric pressure plasma assembly

(76) Inventors: Peter Dobbyn, Midleton Co Cork (IE); Frank Swallow, Castlemartyr Co Cork (IE); Stuart Leadley, Midleton Co Cork (IE)

Correspondence Address: MCKELLAR IP LAW, PLLC, 784 SOUTH POSEYVILLE ROAD, MIDLAND, MI, 48640, US

(21) Appl. No.: 10/496,021

(22) PCT Filed: Apr. 8, 2003
(86) PCT No.: PCT/EP03/04345

§ 371 Date: Jun. 3, 2004

(30) Foreign Application Priority Data
Apr. 10, 2002 (GB) 0208259.2
Apr. 10, 2002 (GB) 028263.4

(51) Int. Cl. C23C 16/00

(52) U.S. Cl. 118/723 E

(57) ABSTRACT

An atmospheric plasma generation assembly (100) having a body (17) containing a reactive agent introducing means, a process gas introducing means and one or more multiple parallel electrode arrangements adapted for generating a plasma. Each electrode arrangement having at least one partially dielectric coated electrode (3, 4) said assembly being adapted such that the only means of exit for a process gas and atomised liquid or solid reactive agent introduced into said assembly is through the plasma region (6) between the aforementioned electrodes (3, 4). The assembly is adapted to move relative to a substrate (1) substantially adjacent to the aforementioned electrodes outermost tips (23). The assembly may also comprise an extractor unit surrounding the plasma generating assembly, comprising an extractor body (8) which is adapted to isolate the assembly from external atmosphere and provide a means of removing exhaust process gas, reactive agents and by-products.

The present invention relates to an atmospheric pressure plasma assembly and a method of treating a substrate using said assembly.

When matter is continually supplied with energy, its temperature increases and it typically transforms from a solid to a liquid and, then, to a gaseous state. Continuing to supply energy causes the system to undergo yet a further change of state in which neutral atoms or molecules of the gas are broken up by energetic collisions to produce negatively charged electrons, positive or negatively charged ions and other species. This mix of charged particles exhibiting collective behaviour is called “plasma”, the fourth state of matter. Due to their electrical charge, plasmas are highly influenced by external electromagnetic fields which make them readily controllable. Furthermore, their high energy content allows them to achieve processes which are impossible or difficult through the other states of matter, such as by liquid or gas processing.

The term “plasma” covers a huge range of systems whose density and temperature vary by many orders of magnitude. Some plasmas are very hot and all their microscopic species (ions, electrons, etc.) are in approximate thermal equilibrium, the energy input into the system being widely distributed through atomic/molecular level collisions. Other plasmas, however, particular those at low pressure (e.g. 100 Pa) where collisions are relatively infrequent, have their constituent species at widely different temperatures and are called “non-thermal equilibrium” plasmas. In these non-thermal plasmas the free electrons are very hot with temperatures of many thousands of Kelvin (K) whilst the neutral and ionic species remain cool. Because the free electrons have almost negligible mass, the total system heat content is low and the plasma operates close to room temperature thus allowing the processing of temperature sensitive materials, such as plastics or polymers, without imposing a damaging thermal burden. The hot electrons create, through high energy collisions, a rich source of radicals and excited species with a high chemical potential energy capable of profound chemical and physical reactivity. It is this combination of low temperature operation plus high reactivity which makes non-thermal plasma technologically important and a very powerful tool for manufacturing and material processing as it is capable of achieving processes which, if achievable at all without plasma, would require very high temperatures or noxious and aggressive chemicals.

For industrial applications of plasma technology, a convenient method is to couple electromagnetic power into a volume of process gas which can be mixtures of gases and vapours in which the workpieces/samples to be treated are immersed or passed through. The gas becomes ionised into plasma, generating chemical radicals, UV-radiation, and ions which react with the surface of the samples. By correct selection of process gas composition, driving power frequency, power coupling mode, pressure and other control parameters, the plasma process can be tailored to the specific application required by a manufacturer.

Because of the huge chemical and thermal range of plasmas, they are suitable for many technological applications. Non-thermal equilibrium plasmas are particularly effective for surface activation, surface cleaning, material etching and coating of surfaces.

The surface activation of polymeric materials is a widely used industrial plasma technology pioneered by the automotive industry. Thus, for example, polyolefins, such as polyethylene and polypropylene, which are favoured for their recycling purposes, have a non-polar surface and consequently a poor disposition to coating or gluing. However, treatment by oxygen plasma results in the formation of surface polar groups giving high wettability and consequently excellent coverage and adhesion to metal paints, adhesives or other coatings. Hence, plasma surface engineering is becoming increasingly important in the manufacture of vehicle fascias, dashboards, bumpers and the like as well as in component assembly in the toy and like industries. Many other applications are available in the printing, painting, gluing, laminating and general coating of components of all geometries in polymer, plastic, ceramic/inorganic, metal and other materials.

The increasing pervasiveness and strength of environmental legislation world-wide is creating substantial pressure on industry to reduce or eliminate the use of solvents and other wet chemicals in manufacturing, particularly for component/surface cleaning. In particular, CFC-based degreasing operations have been largely replaced by plasma cleaning technology operating with oxygen, air and other non-toxic gases. Combining water based pre-cleaning operations with plasma applications allows even heavily soiled components to be cleaned, with the resulting surface qualities obtained being superior to those resulting from traditional methods. Any organic surface contamination is rapidly scavenged by room temperature plasma and converted to gaseous CO₂ and water which can be safely exhausted.

Plasmas can also carry out etching of a bulk material, i.e. for the removal of unwanted material therefrom. Thus, for example, an oxygen based plasma will etch polymers, a process used in the production of circuit boards, etc. Different materials such as metals, ceramics and inorganics are etched by careful selection of precursor gas and attention to the plasma chemistry. Structures down to nanometre critical dimension are now being produced by plasma etching technology.

A plasma technology that is rapidly emerging into mainstream industry is that of plasma coating/thin film deposition. Typically, a high level of polymerisation is achieved by application of plasma to monomeric gases and vapours. Thus, a dense, tightly knit and three-dimensionally connected film can be formed which is thermally stable, chemically very resistant and mechanically robust. Such films are deposited conformally on even the most intricate of surfaces and at a temperature which ensures a low thermal burden on the substrate. Plasmas are therefore ideal for the coating of delicate and heat sensitive, as well as robust materials. Plasma coatings are free of micropores even with thin layers. The optical properties, e.g. colour, of the coating can often be customised and plasma coatings adhere well to even non-polar materials, e.g. polyethylene, as well as steel (e.g. anti-corrosion films on metal reflectors), ceramics, semiconductors, textiles, etc.

In all these processes, plasma engineering produces a surface effect customised to the desired application or product without affecting the material bulk in any way. Plasma processing thus offers the manufacturer a versatile and powerful tool allowing choice of a material for its bulk technical and commercial properties while giving the freedom to independently engineer its surface to meet a totally different set of needs and confers greatly enhanced product functionality, performance, lifetime and quality which provides the user a significant added value to its production capability.

These properties provide a strong motivation for industry to adopt plasma-based processing, and this move has been led since the 1960s by the microelectronics community which has developed the low pressure Glow Discharge plasma into an ultra-high technology and high capital cost engineering tool for semiconductor, metal and dielectric processing. The same low pressure Glow Discharge type plasma has increasingly penetrated other industrial sectors since the 1980s offering, at more moderate cost, processes such as polymer surface activation for increased adhesion/bond strength, high quality degreasing/cleaning and the deposition of high performance coatings. Thus, there has been a substantial take-up of plasma technology. Glow discharges can be achieved at both vacuum and atmospheric pressures. In the case of atmospheric pressure glow discharge, gases such as helium or argon are utilised as diluents and a high frequency (e.g.>1 kHz) power supply is used to generate a homogeneous glow discharge at atmospheric pressure via a Penning ionisation mechanism, (see for example, Kanazawa et al, J. Phys. D: Appl. Phys. 1988, 21, 838, Okazaki et al, Proc. Jpn. Symp. Plasma Chem. 1989, 2, 95, Kanazawa et al, Nuclear Instruments and Methods in Physical Research 1989, B37/38, 842, and Yokoyama et al., J. Phys. D: Appl. Phys. 1990, ,3 374).

However, adoption of plasma technology has been limited by a major constraint on most industrial plasma systems, namely, their need to operate at low pressure. Partial vacuum operation means a closed perimeter, sealed reactor system providing only off-line, batch processing of discrete work pieces. Throughput is low or moderate and the need for vacuum adds capital and running costs.

Atmospheric pressure plasmas, however, offer industry open port or perimeter systems providing free ingress into and exit from the plasma region by workpieces/webs and, hence, on-line, continuous processing of large or small area webs or conveyor-carried discrete webs. Throughput is high, reinforced by the high species flux obtained from high pressure operation. Many industrial sectors, such as textiles, packaging, paper, medical, automotive, aerospace, etc., rely almost entirely upon continuous, on-line processing so that open port/perimeter configuration plasmas at atmospheric pressure offer a new industrial processing capability.

Corona and flame (also a plasma) treatment systems have provided industry with a limited form of atmospheric pressure plasma processing capability for about 30 years. However, despite their high manufacturability, these systems have failed to penetrate the market or be taken up by industry to anything like the same extent as the lower pressure, bath-processing-only plasma type. The reason is that corona/flame systems have significant limitations. They operate in ambient air offering a single surface activation process and have a negligible effect on many materials and a weak effect on most. The treatment is often non-uniform and the corona process is incompatible with thick webs or 3D webs while the flame process is incompatible with heat sensitive substrates. It has become clear that atmospheric pressure plasma technology must move much deeper into the atmospheric pressure plasma spectrum to develop advanced systems meeting industry needs.

Significant advances have been made in plasma deposition at atmospheric pressure. Considerable work has been done on the stabilisation of atmospheric pressure glow discharges, such as described in Okazaki et al. J. Phys. D: Appl. Phys. 26 (1993) 889-892. Further, U.S. Pat. Specification No. 5,414,324 describes the generation of a steady-state glow discharge plasma at atmospheric pressure between a pair of electrically insulated metal plate electrodes spaced up to 5 cm apart and radio frequency (RF) energised with a root means square (rms) potential of 1 to 5 kV at 1 to 100 kHz U.S. Pat. No. 5,414,324 also discusses the problems with electrode plates and the need to discourage electrical breakdown at the tips of electrodes and describes a water cooling system which is supplied through fluid flow conduits bonded to the electrodes in which water does not come into direct contact with any electrode surface.

In U.S. Pat. Specification No. 5,185,132, there is described an atmospheric plasma reaction method in which plate electrodes are used in a vertical configuration. However, they are merely used in the vertical configuration to prepare the plasma and then the plasma is directed out from between the plates onto a horizontal surface below the vertically arranged electrodes.

In the applicants co-pending application WO 02/28548, which was published after the priority date of the present application, there is provided an atmospheric plasma glow discharge apparatus designed for plasma treating substrates with liquids or solids introduced into the plasma stream through an atomiser or the like.

In JP 07-0062546 and U.S. Pat. No. 6,086,710 there are provided plasma treating apparatus which describe several alternative ways of removing process gas, gaseous reactive agents and by-products and the like after passing through a plasma.

In EP 0431951 an atmospheric plasma assembly is provided for treating substrates with species produced by plasma treating a noble gas/reactive gas mixture. Electrodes at least partially coated in dielectrics are positioned parallel to each other and are vertically aligned such that they are perpendicular to substrate which passes beneath a slit between electrodes. The assembly requires an integral surface treatment unit which effectively restricts the width of any substrate to be treated by the width of the surface treatment unit and as such renders the system cumbersome.

In WO 02/40742 which was published after the priority date of the present application there is discussed a method and device for atmospheric plasma processing a substrate with gases. JP 2002-57440 describes an atmospheric plasma processing method for treating circuit boards with gases using pulsed voltages to enhance surface treatment of the circuit boards. None of these documents discuss even the likelihood of the introduction of a liquid or solid coating making material into an apparatus of the type disclosed in the present invention.

The inventors have now identified an assembly which will overcome a number of problems with the prior art equipment, i.e. in the present invention, an integral surface treatment unit is not required and the plasma treatment is not restricted solely to treating substrates with gases. A number of additional improvements will be identified in the following description.

In a first embodiment of the invention there is provided an atmospheric plasma generation assembly having an atmospheric plasma generation unit with a body containing a reactive agent introducing means, a process gas introducing means and one or more multiple parallel electrode arrangements adapted for generating a plasma, each arrangement having at least one partially dielectric coated electrode, said assembly being adapted such that the only means of exit for a process gas and reactive agent introduced into said assembly is through the plasma region between the aforementioned electrodes said assembly being adapted to move relative to a substrate substantially adjacent to the aforementioned electrodes outermost tips, characterised in that the reactive agent introducing means is an atomiser for atomising a reactive agent in the form of a liquid and/or solid coating-forming material.

The atmospheric plasma generation unit body may have any suitable geometry but is preferably elongate and has a substantially square, circular, rectangular or elliptical cross-section, of which circular is most preferred. Preferably, the body is made from a dielectric material and serves as a means of distributing process gas and reactive agent into and through the plasma region between the parallel electrodes of the electrode arrangement. The atmospheric plasma generation assembly body may be of any required length although it is preferred that it will not be shorter than 0.5 m in length. Optionally the body may be of variable length (dependent on the width of the substrate being treated) but is preferably a maximum of 20 m in length, more preferably a maximum of 10 m in length and most preferably a maximum of 5 metres in length, wherein the length is the approximate length of each electrode and therefore of the plasma region generated between adjacent pairs of parallel electrodes. When substrates of greater dimensions than the assembly body are to be treated, this may be undertaken by treating a section of substrate at a time until the whole substrate has been treated, or by the provision of a multiple number of assemblies utilised to treat the whole of the substrate in a single action. In the latter case, it may be preferable to have the multiple assemblies positioned in an offset row to ensure treatment of the whole substrate.

The reactive agent introducing means preferably comprises an atomiser or nebuliser or the like of the type described in the applicants co-pending patent application WO 02/28548, the contents of which are incorporated herein. Whilst the atomised liquid and/or solid coating-forming material may be atomised using any suitable form of atomiser or nebuliser, a preferred example is an ultrasonic nozzle.

The atomiser preferably produces a coating-forming material drop size of from 10 to 100 μm, more preferably from 10 to 50 μm. Suitable atomisers for use in the present invention include ultrasonic nozzles from Sono-Tek Corporation, Milton, N.Y., USA or Lechler GmbH of Metzingen Germany. The apparatus of the present invention may include a plurality of atomisers, which may be of particular utility, for example, where the apparatus is to be used to form a copolymer coating on a substrate from two different coating-forming materials, where the monomers are immiscible or are in different phases, e.g. the first is a solid and the second is gaseous or liquid.

Any suitable means may be utilised to introduce the process gas into the assembly. Any appropriate means of delivery may be used to transport the process gas and reactive agent into the plasma region between adjacent electrodes. In the case where a single process gas introducing means and a single reactive agent introducing means are utilised, the electrodes may be spaced apart by means of an electrode spacer. The electrode spacer serves as a variable slit process gas/reactive agent distributor, such that equal flow rates into the plasma region are provided along the length of the plasma region. The electrode spacer may alternatively be a multi-port plate or the like used to provide equal flow rates into the plasma region along the whole length of the plasma region. This electrode spacer may simply be in the form of a slit having a wedge-shaped cross-section such that the slit is at its broadest the furthest points away from the process gas/reactive agent introducing means and narrowest at points closest to the process gas/reactive agent introducing means. Alternatively, there may be provided an array of each process gas/reactive agent introducing means situated along the length of the body. In either case support struts may be utilised, where required, to maintain a predetermined distance between electrodes at each point along the length of the plasma region.

The introduction of an atomised liquid by means of an ultrasonic spray nozzle will require a frequency generation cable and may be adapted such that atomised liquid is introduced directly (i.e. by direct injection) or with a carrier gas such as air into the nozzle. For effective plasma treatment, it is important to ensure an even distribution of the atomised spray. This may be carried out by any suitable means however, the following options are preferred:-
i. Process gas is introduced perpendicular to the axis of the body such that turbulence is generated close to the ultrasonic spray nozzle outlet as the gas flow reorientates to the main direction of flow along the length of the axis. This is best suited to higher flow rates that may be seen when using low cost process gases such as air or nitrogen.
ii. Turbulence is induced by positioning a restrictive flow disc in the process gas flow field just upstream of the ultrasonic spray nozzle tip. Turbulence will be present within 6 disc diameters downstream of the disc, so ensuring homogeneity of the liquid spray (based on the body having a circular cross-section and the disc diameter is approximately half that of the body.
iii. The ultrasonic spray nozzle may alternatively be mounted on the end of the main pipe such that it lies along the axis. In this position, side entry of carrier gas is preferred.

Optionally a gaseous reactive agent may additionally be utilised, in which case the process gas introducing means and gaseous reactive agent introducing means may be the same or different. When a gaseous reactive agent is additionally required, the process gas introducing means may be utilised to introduce both the process gas and where required the gaseous reactive agent.

Each of the at least one multiple parallel electrode arrangements adapted for generating a plasma, has one or more at least partially dielectric coated electrodes. Two particular electrode arrangements are preferred for the present invention, the first is particularly preferred for non-conducting substrates and comprises one or more pairs of at least partially dielectric coated parallel electrodes situated a predetermined distance apart.

The second particularly preferred arrangement is specifically for conducting substrates and comprises a three parallel electrode system whereby a central electrode is at least partially dielectric coated. The other two electrodes are situated one on each side of the central electrode at a predetermined distance apart therefrom, both are substantially uncoated with dielectric and both are earthed such that in use they act to prevent shorting between the central electrode and a conductive substrate being treated. Preferably, the central electrode is adapted to have an adjustable distance between the electrode and the substrate surface. Preferably, the central electrode is encased in a dielectric and more preferably, the dielectric is thicker at the electrode tip nearest to the substrate surface

It is to be understood that the term conductive and non-conductive are intended to relate in particular to electrically conducting (metals) and electrically non-conducting (plastics) substrates.

Each electrode may be made in any suitable form, such as, merely for example, a metallic plate or mesh electrode which may be made from any suitable metal such as stainless steel, copper or brass but is preferably made of stainless steel and may have any appropriate geometry. Preferably, the electrodes are made from elongated strips of stainless steel. Preferably, at least two sides of each electrode in the two electrode arrangement and the central electrode in the three electrode arrangement are covered by a suitable dielectric; most preferably, the electrodes are encased in a dielectric material. The electrodes preferably project outwardly from the body in order to ensure a minimal distance between the tip of each electrode and the substrate surface.

The dielectric material used in accordance with the present invention to at least partially cover one of the electrodes may be any suitable dielectric material, examples include but are not restricted to polycarbonate, polyethylene, glass, glass laminates, epoxy filled glass laminates, ceramics and the like. The metal electrodes may be bonded to the dielectric material either by adhesive or by some application of heat and fusion of the metal of the electrode to the dielectric material. Similarly, the electrode may be encapsulated within the dielectric material.

The generation of steady-state glow discharge plasma at atmospheric pressure is preferably obtained between parallel electrode arrangements which may be spaced up to 5 cm apart, dependent on the process gas used. The electrodes are radio frequency energised with a root mean square (rms) potential of 1 to 100 kV, preferably between 4 and 30 kV at 1 to 100 kHz, preferably at 15 to 40 kHz. The voltage used to form the plasma will typically be between 2.5 and 30 kV, most preferably between 2.5 and 10 kV however the actual value will depend on the chemistry/gas choice and plasma region size between the electrodes.

The applicants have found that the plasma generated by the electrode arrangements as described above extends to at least between 0.5-2.0 cm beyond the opposing surfaces of the electrodes. Hence, for example, if the sides of each electrode which face each other are rectangular and measure 5 cm by 10 cm the plasma region generated using such electrodes would be a minimum of 6 cm by 11 cm, and as such, providing the shortest distance between the electrode tip and the substrate surface is no greater than about 2 cm, the substrate surface can be said to be within and not downstream of the plasma region (as described in EP0431951). For the latter reason when the electrodes are encased in dielectric it is preferred that the dielectric encasement is no greater than 2 mm in thickness, at least in relation to the tip of the electrode in closest proximity to the substrate surface.

Preferably the assembly is adapted to move relative to a substrate substantially adjacent to the aforementioned electrodes outermost tips, such that the atmospheric plasma treatment of the substrate surface is carried out downstream of said electrodes. Relative movement of the assembly and the substrate may take the form of a stationary assembly and a movable substrate by means of a roller system, the substrate being in the form of a reel to reel web or a conveyor belt or the like. Alternatively, relative movement may be considered to take the form of there being a stationary substrate with a movable assembly. The latter arrangement may be most suitable for particularly large sheeted substrates such as steel and aluminium sheets, in which case motion of the assembly is preferably controlled by computer operation which predefines the motion of the assembly to ensure the whole substrate is evenly treated.

Whilst it may be preferred for the electrodes to be vertically aligned and the substrate to move along a horizontal plane this is not essential and the assembly may be adapted to treat any required substrate surface, such as for example a section of the body or wing of an aircraft. It should be understood that the term vertical is intended to include substantially vertical and should not be restricted solely to electrodes positioned at 90 degrees to the horizontal.

Where required, additional assemblies may be added to the system to form further successive plasma regions through which a substrate would pass. The additional units may be situated before or after said assembly described above such that substrate may be subjected to pre-treatment or post-treatment steps. Treatments applied in the plasma regions formed by the additional assemblies may be the same or different from that undertaken in the assembly described above.

Whilst the assembly in accordance with the present invention may operate at any suitable temperature, it will preferably operate at a temperature between room temperature (20° C.) and 70° C. and is typically utilized at a temperature in the region of 30 to 50° C.

Preferably, the assembly in accordance with the present invention additionally comprises an extractor unit. The extractor unit preferably comprises an extractor body, which takes the form of a hood which, when in use, is adapted to isolate the plasma assembly from external atmosphere. The extractor unit further comprises a means of removing exhaust process gas, reactive agents and by-products which enter the extractor unit after passing through both the plasma region and the gap between the lower tips of the electrodes and the substrate surface. The means of removing exhaust process gas, reactive agents and by-products is situated in the body exhaust body and is preferably a pump or the like or merely an exhaust pipe that process gas, reactive agents and by-products are removed from the extractor unit and are then collected for separation, disposal and/or re-use. It is particularly preferred that the process gas, which typically contains a substantial proportion of one or more expensive noble gases, such as helium or argon, is recycled. Alternatively a gas typically an inert gas such as nitrogen may be introduced into the extractor unit which may be used to direct process gas, reactive agent and by-products and the like towards the means of removing exhaust process gas, reactive agents and by-products whilst being physically prevented from entering the plasma region by the lips or an alternative suitable geometry.

Preferably, the extractor body is shaped so as to form an open channel around the body of the plasma generating assembly, such that in use, the edges of the extractor body in the proximity of the substrate surface substantially form a chamber around the electrodes in combination with the substrate, thereby substantially forming a seal against the atmosphere.

The extractor body may be of any suitable cross-section but preferably has substantially the same cross-sectional shape as the cross-sectional shape of the atmospheric pressure plasma generation unit body but has larger cross-sectional dimensions such that there is a gap between outer walls of atmospheric pressure plasma generation unit body and the inner surface of the extractor body which forms the open channel described above. In use the substrate surface and the extractor body form a chamber around the atmospheric pressure plasma generation unit body. The provision of this chamber substantially prevents the escape of process gas, reactive agents and by-products other than through the extractor unit and substantially ensures isolation of the atmospheric pressure plasma generation unit body from the atmosphere.

The edges of the extractor unit which are near most or brought into contact with the substrate surface, may be made of any suitable material, and if they are brought into contact with the substrate must be chosen from materials which will substantially not damage the substrate surface. The edges of the extractor unit, which are near most or brought into contact with the substrate surface may be in the form of lips, which are outwardly projecting from the body of the extractor unit. The lips are preferably designed to be substantially equidistant from the substrate surface as the electrode tips, more preferably the edges of the extractor unit which are near most or brought into contact with the substrate surface are closer to the substrate surface than the electrode tips or in contact with the substrate surface, providing such contact will not negatively effect the plasma treatment of the substrate surface.

The extractor body is preferably made from a dielectric substance, such as for example, polyvinyl chloride (PVC) or polypropylene. The extractor body serves not only to extract the above but also acts as a safety shield by shielding the electrodes and provides an increased area for thermal management of the electrodes such that overheating (and the resulting damage) can be avoided during, for example plasma generation in air where high voltages and heat loads are required and/or encountered.

In use, as the process gas, reactive agents and by-products are drawn into the channel after passing through the plasma region they effectively cool the assembly such that the plasma treatment of substrates utilising the assembly of the present invention operates at the low temperatures mentioned above, with the temperature preferably never being greater than about 50° C. This is particularly important where air is being used in the process gas as the voltages and heat loads are higher than when using helium as process gas. The extractor unit of the present invention is adapted to ensure that minimum and preferably no toxic gases resulting from the plasma treatment escape into the atmosphere.

One or more conditioning bars may be arranged external to the lips of the extractor. These conditioning bars are preferably adapted to be in contact or adjacent to the substrate surface both before and after the substrate has been plasma treated. The conditioning bars are provided to limit/exclude the ingress of air or the like into the extractor from the atmosphere. They may be in the form of lip seals in contact with the substrate surface and/or anti-static bars, of the type used in the plastic film industry, which are adapted to remove static from the surface of the substrate using high static potential and optionally air jets to remove dust particulates. Antistatic carbon brushes and electrostatic barrier guns may also be used. In the case of the electrostatic barrier guns, corona type electrode based devices such as described in U.S. Pat. No. 6,285,032 are particularly preferred to act as a barrier means preventing the ingress of air into the extractor and preventing the loss of process gas into the atmosphere enabling said process gas to be collected and reused.

In an alternative embodiment which is particularly useful for treating substrates which the process gas and reactive agent tends to pass through such as non-woven and woven textile webs and the like rather than being around the assembly body the extractor unit may be positioned underneath the substrate such that the substrate is transported between the assembly body and the extractor unit and the extractor unit may be adapted to draw the process gas and reactive agent through the substrate, leading to an evenly treated substrate.

In a further embodiment of the invention there is provided a method of treating a surface of a substrate with an assembly of the type described above comprising:- introducing a process gas and an atomised liquid and/or solid coating-forming material into the atmospheric plasma generation assembly body affecting a plasma, plasma treating the atomised liquid and/or solid coating-forming material and treating the surface of a substrate with the resulting activated species generated thereby.

In a still further embodiment of the invention there is provided an atmospheric plasma generation assembly, adapted to be used to coat a substrate, having an atmospheric plasma generation unit with a body containing a reactive agent introducing means, a process gas introducing means and one or more multiple parallel electrode arrangements adapted for generating a plasma, each arrangement having at least one partially dielectric coated electrode, said assembly being adapted such that the only means of exit for a process gas and reactive agent introduced into said assembly is through the plasma region between the aforementioned electrodes characterised in that the reactive agent introducing means is an atomiser for atomising a reactive agent in the form of a liquid and/or solid coating-forming material.

Preferably in the case of this embodiment a suitable substrate may be a powder which may be introduced into the assembly by way of a third introduction means which may comprises a suitable powder introduction means such as, for example, a powder spray gun or the like. The post-introduction mixing of powder in accordance with this embodiment of the invention is preferably adapted to be the same as the means of introducing and mixing the atomised liquid or solid coating forming material with the carrier gas, as described in paragraph 27 above. It is important to ensure an even distribution of the powder in the process gas and atomised solid or liquid coating forming material.

The coated powdered substrate may be collected on or in any suitable means, for example the treated powder may be collected on an electrostatic conveyor belt.

Alternatively the plasma assembly of the present invention may be fixed at or near to an open base of a powder container such as a hopper or shute in which the powder passing through a narrow opening in the base thereof may be fluidised using an appropriate fluidising gas such that powder exiting the container causes a venturi effect, resulting in the entrainment of the process gas/atomised liquid or solid coating material mixture exiting from the plasma assembly such that the powder particles entering the atmospheric pressure plasma discharge and/or an ionised gas stream resulting therefrom being coated with the atomised liquid or solid coating forming material leaving the assembly of the invention

This embodiment of the present invention is particularly useful in relation to the coating of powdered substrates which are sensitive to other coating processes, such as for example, coating powdered substrates which are sensitive to, for example, heat, temperature and UV light. The powdered substrates to be coated may comprise any material, for example metals, metal oxides, silica, carbon, organic powdered substrates, including polymeric, dyestuffs, fragrances, flavourings, pharmaceutical powdered substrates such as penicillins and antibiotics as well as biologically active compounds for example protein based materials and enzymes.

A wide variety of plasma treatments are currently available, those of particular importance to the present invention are surface activation, surface cleaning, material etching and coating applications. Typically, the substrate may be subjected to any appropriate treatment using one or more assemblies. For example, a first assembly may be utilised to clean the substrate surface and a second assembly may be used for surface activation, coating or etching. Additional assemblies might be utilised to activate the coated surface and then re-coat the surface, apply one or more further coatings or the like, dependent on the application for which the substrate is intended. For example, a coating formed on a substrate may be post treated in a range of plasma conditions. For example, siloxane derived coatings may be further oxidised by oxygen containing plasma treatment. The oxygen containing plasma being generated by entry oxygen containing materials to the plasma such as oxygen gas or water.

Any appropriate combination of plasma treatments may be used, for example the first plasma region may be utilised to clean the surface of the substrate by plasma treating using a helium gas plasma and the second plasma region is utilised to apply a coating, for example, by application of a liquid or solid spray through the atomiser or nebuliser described above

Alternatively a first assembly might be utilised as a means of oxidation (in for example, an oxygen/Helium process gas) or for the application of a coating and the second plasma region is utilised to apply a second coating using a different precursor. As an example having a pre-treatment and post-treatment step is the following process adapted for the preparation of a SiOx barrier with a soil/fuel resistant outer surface which may be utilised for solar cells or in automobile applications in which the substrate is first pretreated by He cleaning/activation of substrate, followed by deposition of SiOx from a polydimethylsiloxane precursor in the first plasma region, Further Helium plasma treatment may then be utilised to provide extra cross-linking of the SiOx layer and finally applying a coating utilizing a perfluorinated precursor.

The present invention may be used to form many different types of substrate coatings. The type of coating which is formed on the substrate is determined by the coating-forming material(s) used, and the present method may be used to (co)polymerise coating-forming monomer material(s) onto the substrate surface. The coating-forming material may be organic or inorganic, solid, liquid or gaseous, or mixtures thereof. Suitable organic coating-forming materials include carboxylates, methacrylates, acrylates, styrenes, methacrylonitriles, alkenes and dienes, for example methyl methacrylate, ethyl methacrylate, propyl methacrylate, butyl methacrylate, and other alkyl methacrylates, and the corresponding acrylates, including organofunctional methacrylates and acrylates, including glycidyl methacrylate, trimethoxysilyl propyl methacrylate, allyl methacrylate, hydroxyethyl methacrylate, hydroxypropyl methacrylate, dialkylaminoalkyl methacrylates, and fluoroalkyl (meth)acrylates, methacrylic acid, acrylic acid, fumaric acid and esters, itaconic acid (and esters), maleic anhydride, styrene, α-methylstyrene, halogenated alkenes, for example, vinyl halides, such as vinyl chlorides and vinyl fluorides, and fluorinated alkenes, for example perfluoroalkenes, acrylonitrile, methacrylonitrile, ethylene, propylene, allyl amine, vinylidene halides, butadienes, acrylamide, such as N-isopropylacrylamide, methacrylamide, epoxy compounds, for example glycidoxypropyltrimethoxysilane, glycidol, styrene oxide, butadiene monoxide, ethyleneglycol diglycidylether, glycidyl methacrylate, bisphenol A diglycidylether (and its oligomers), vinylcyclohexene oxide, conducting polymers such as pyrrole and thiophene and their derivatives, and phosphorus-containing compounds, for example dimethylallylphosphonate. Suitable inorganic coating-forming materials include metals and metal oxides, including colloidal metals. Organometallic compounds may also be suitable coating-forming materials, including metal alkoxides such as titanates, tin alkoxides, zirconates and alkoxides of germanium and erbium.

Substrates may alternatively be provided with silica- or siloxane-based coatings using coating-forming compositions comprising silicon-containing materials. Suitable silicon-containing materials include silanes (for example, silane, alkylsilanes, alkylhalosilanes, alkoxysilanes) and linear (for example, polydimethylsiloxane) and cyclic siloxanes (for example, octamethylcyclotetrasiloxane), including organo-functional linear and cyclic siloxanes (for example, Si—H containing, halo-functional, and haloalkyl-functional linear and cyclic siloxanes, e.g. tetramethylcyclotetrasiloxane and tri(nonofluorobutyl)trimethylcyclotrisiloxane). A mixture of different silicon-containing materials may be used, for example to tailor the physical properties of the substrate coating for a specified need (e.g. thermal properties, optical properties, such as refractive index, and viscoelastic properties).

An advantage of the present invention over the prior art is that both liquid and solid atomised coating-forming materials may be used to form substrate coatings, due to the method of the present invention taking place under conditions of atmospheric pressure. Furthermore the coating-forming materials can be introduced into the plasma discharge or resulting stream in the absence of a carrier gas, i.e. they can be introduced directly by, for example, direct injection, whereby the coating forming materials are injected directly into the plasma.

The process gas for use in plasma treatment processes using the electrodes of the present invention may be any suitable gas but is preferably an inert gas or inert gas based mixture such as, for example helium, a mixture of helium and argon, an argon based mixture additionally containing ketones and/or related compounds. These process gases may be utilized alone or in combination with gaseous reactive agents such as, for example, nitrogen, ammonia, O₂, H₂O, NO₂, air or hydrogen. Most preferably, the process gas will be Helium alone or in combination with an oxidizing or reducing gaseous reactive agent. The selection of gas depends upon the plasma processes to be undertaken. When an oxidizing or reducing gaseous reactive agent is required, it will preferably be utilized in a mixture comprising 90-99% noble gas and 1 to 10% oxidizing or reducing gas.

In the case when no oxidising or reducing gas is wanted in the assembly, the assembly may be flushed out with an inert gas or the process gas before initiation of the plasma. Typically, the inert gas might be for example nitrogen.

Under oxidising conditions the assembly in accordance with the present invention may be used to form an oxygen containing coating on the substrate. For example, silica-based coatings can be formed on the substrate surface from atomised silicon-containing coating-forming materials. Under reducing conditions, the present method may be used to form oxygen free coatings, for example, silicon carbide based coatings may be formed from atomised silicon containing coating forming materials.

In a nitrogen containing atmosphere nitrogen can bind to the substrate surface, and in an atmosphere containing both nitrogen and oxygen, nitrates can bind to and/or form on the substrate surface. Such gaseous reactive agents may also be used to pre-treat the substrate surface before exposure to a liquid or solid coating forming substance. For example, oxygen containing plasma treatment of the substrate may provide improved adhesion with the applied coating. The oxygen containing plasma being generated by entry oxygen containing materials to the plasma such as oxygen gas or water.

The substrate to be coated may comprise any suitable material, for example glass, metals such as steel, aluminium, copper, titanium and alloys thereof, plastics for example thermoplastics such as polyolefins e.g. polyethylene, and polypropylene, polycarbonates, polyurethanes, polyvinylchloride, polyesters (for example polyalkylene terephthalates, particularly polyethylene terephthalate), polymethacrylates (for example polymethylmethacrylate and polymers of hydroxyethylmethacrylate), polyepoxides, polysulphones, polyphenylenes, polyetherketones, polyimides, polyamides, polystyrenes, phenolic, epoxy and melamine-formaldehyde resins, and blends and copolymers thereof, siloxane, fabrics, woven or non-woven fibres, natural fibres, synthetic fibres cellulosic material and powder or a blend of an organic polymeric material and a organosilicon-containing additive which is miscible or substantially non-miscible with the organic polymeric material as described in the applicants co-pending patent application WO 01/40359. For the avoidance of doubt “substantially non-miscible” means that the organosilicon-containing additive and the organic material have sufficiently different interaction parameters so as to be non-miscible in equilibrium conditions. This will typically, but not exclusively, be the case when the Solubility Parameters of the organosilicon-containing additive and the organic material differ by more than 0.5 MPa^{1/2}. The present invention is particularly suited for treating rigid or inflexible sheets and the like, for example metal sheets using the three electrode arrangement and plastics using the two electrode arrangement.

Substrates coated using the assembly in accordance with the present invention may have various uses. For example, a silica-based coating, generated in an oxidising atmosphere, may enhance the barrier and/or diffusion properties of the substrate, and may enhance the ability of additional materials to adhere to the substrate surface; a halo-functional organic or siloxane coating (e.g. perfluoroalkenes) may increase hydrophobicity, oleophobicity, fuel and soil resistance, and/or the release properties of the substrate; a polydimethylsiloxane coating may enhance water resistance and release properties of the substrate, and may enhance the softness of fabrics to touch; a polyacrylic acid polymeric coating may be used as an adhesive layer to promote adhesion to substrate surface or as part of laminated structure; the inclusion of colloidal metal species in the coatings may provide surface conductivity to the substrate, or enhance its optical properties. Polythiophene and polypyrrole give electrically conductive polymeric coatings which may also provide corrosion resistance on metallic substrates.

The invention will be more clearly understood from the following description of some embodiments thereof given by way of example only with reference to the accompanying drawings, in which:-

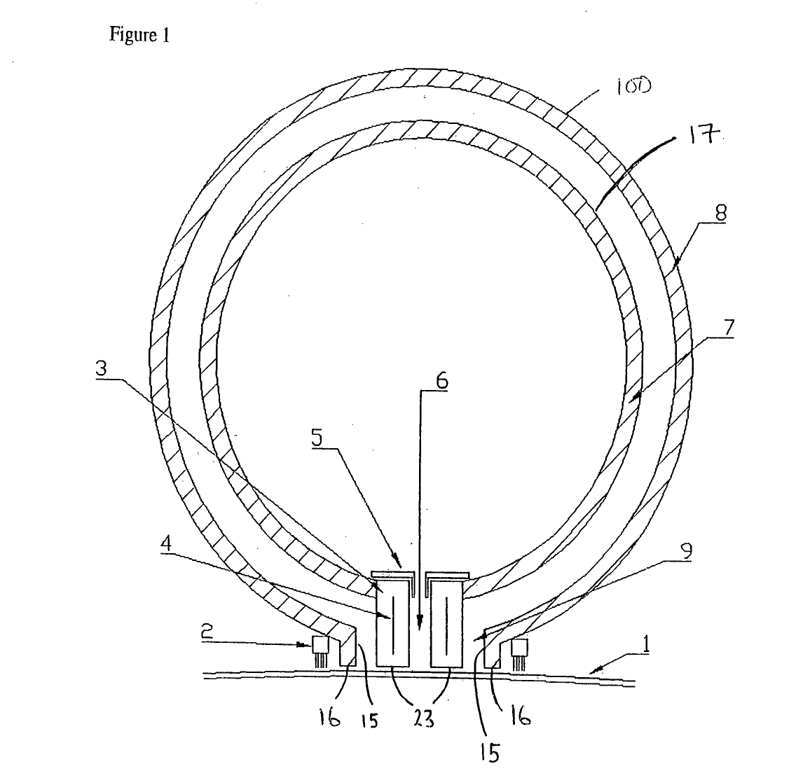

FIG. 1 is a transverse cross-sectional view of an assembly according to the invention using a two electrode arrangement for non-conductive substrates,

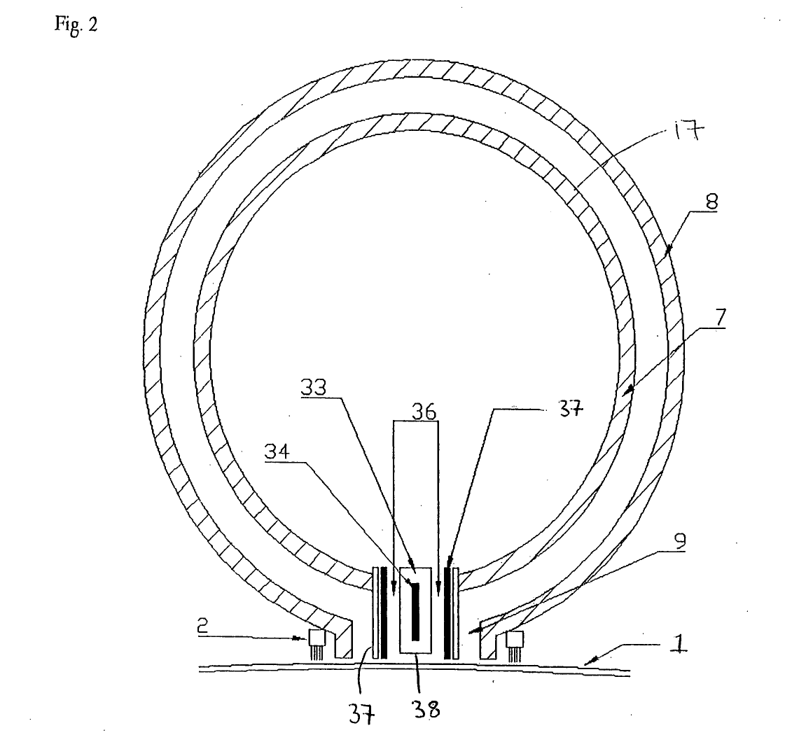

FIG. 2 is a transverse cross-sectional view of an assembly according to the invention using a three electrode arrangement for conductive substrates,

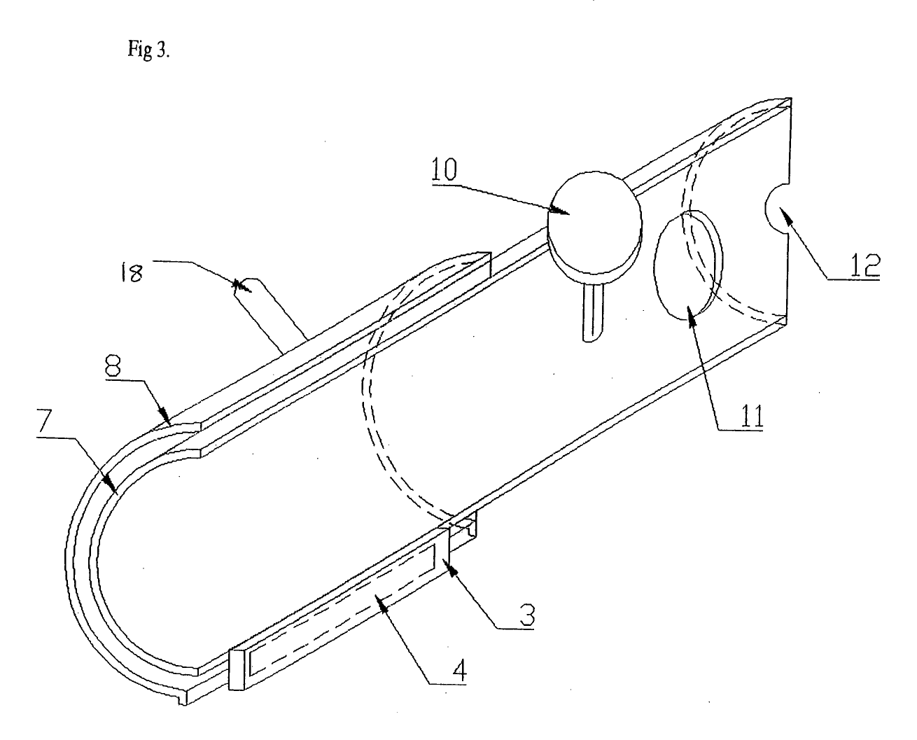

FIG. 3 is an isometric cut-through of an assembly in accordance with the present invention.

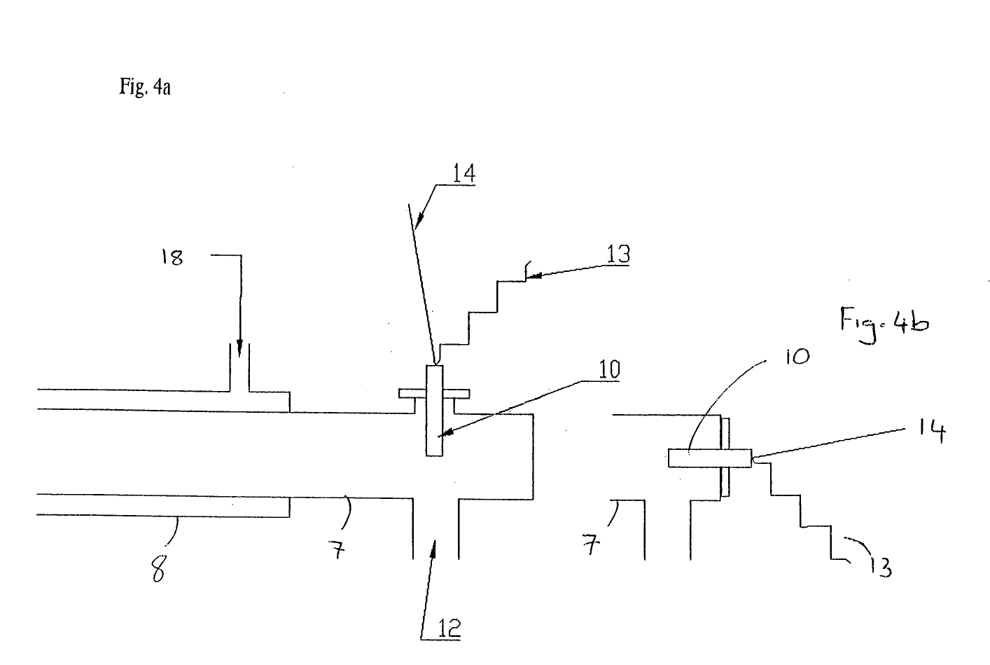

FIG. 4a and 4b are view of a preferred atomised liquid introduction system

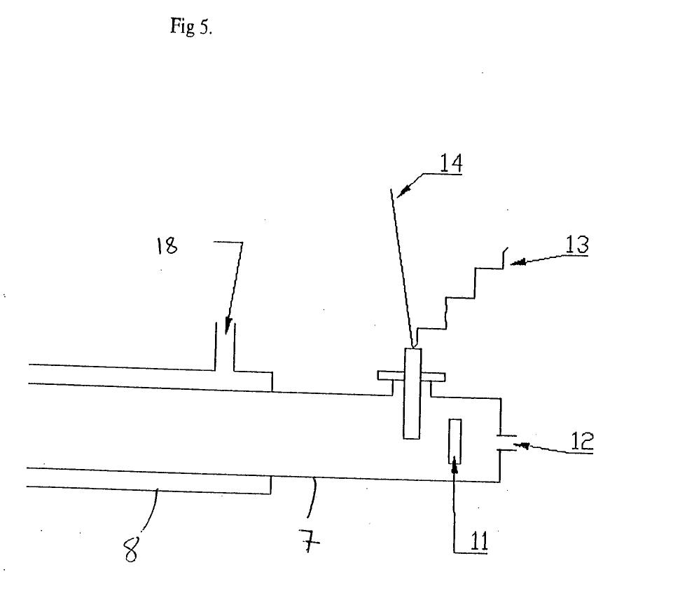

FIG. 5 is a view of an alternative atomised liquid introduction system

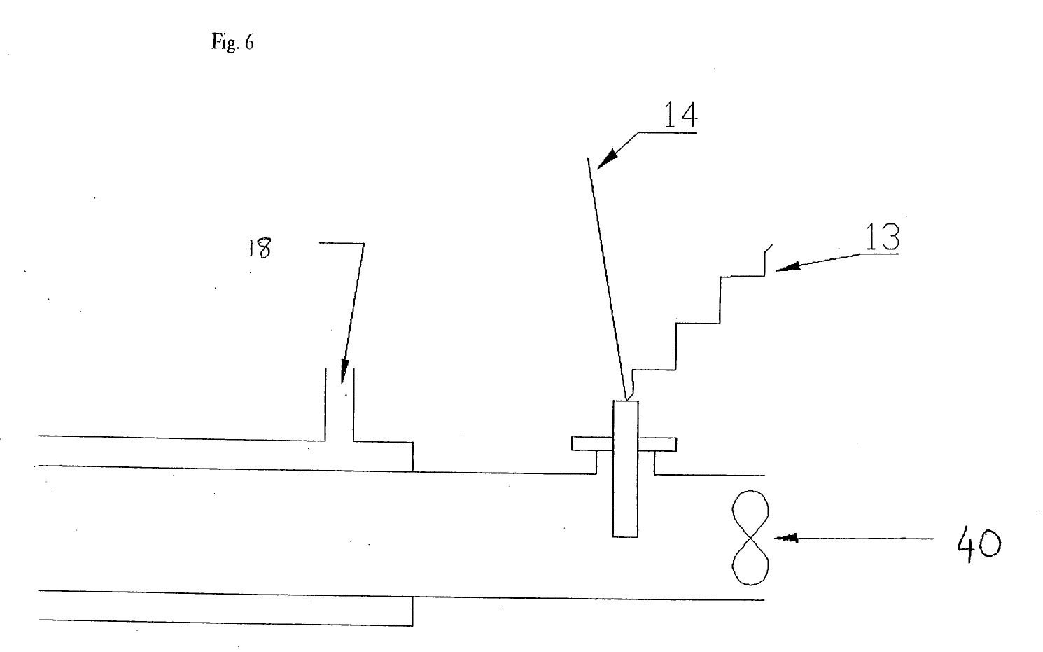

FIG. 6 is a view of an alternative process gas introduction system

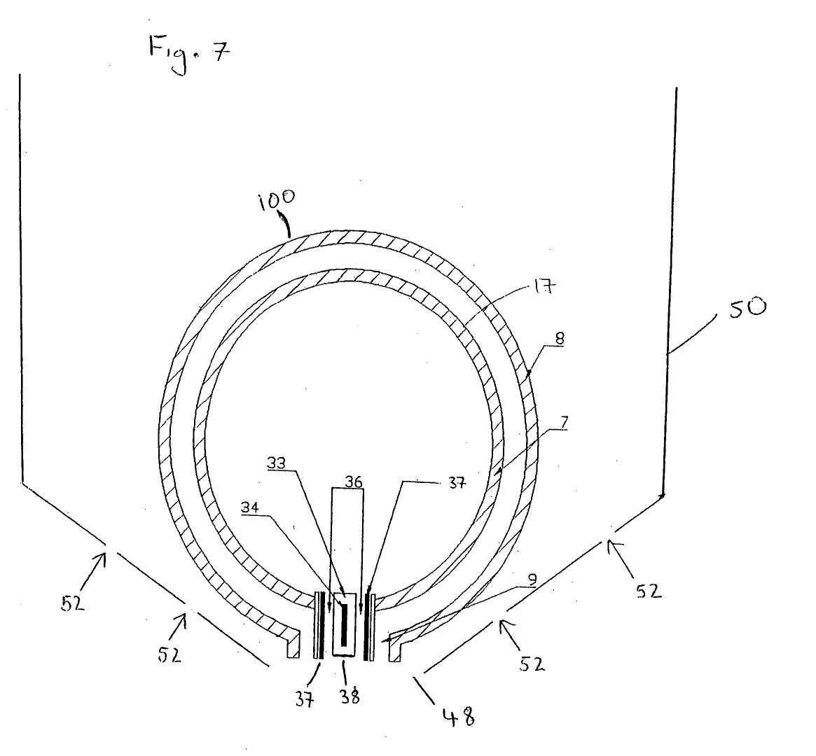

FIG. 7 is a view of an embodiment where the apparatus of the present invention is utilised to treat a powder

Referring to FIGS. 1 and 3 there is provided an atmospheric plasma assembly 100, comprising an atmospheric plasma generation unit 7 which has a substantially cylindrical body 17 having a substantially circular cross-section which contains a process gas inlet 12 for introducing a process gas into unit 7. The process gas is used to affect a plasma. An ultrasonic nozzle 10 is provided for introduction of a reactive agent, which in the present invention is an atomised liquid and/or solid coating-forming material. Unit 7 also contains a pair of electrodes 4 both of which are coated with or encapsulated in a dielectric material 3. The electrodes are maintained at a predetermined distance apart by means of a pair of electrode spacers 5. The dielectric coated electrodes 3, 4 project outwardly from the atmospheric plasma generation unit 7. The atmospheric plasma generation unit 7 is designed such that the only exit for a process gas and reactive agent introduced into the unit 7 is through the plasma region 6 between dielectric coated electrodes 3, 4.

Extractor unit 8, like atmospheric pressure generation unit 7 is generally cylindrical with a substantially circular cross-section and is made of a dielectric material such as polypropylene or PVC. Units 7 and 8 are concentric with extractor unit 8 having a larger diameter. Extractor unit 8 comprises a lip 15, which surrounds the dielectric coated electrodes 3, 4 and forms a channel 9 between electrode 3, 4 and lip 15 through which residual process gas, reactant and by-product is extracted. The end of the lip 16 is designed to be equidistant from substrate 1 as is the base of the dielectric coated electrodes 3, 4 but can be closer. Extractor unit 8 also comprises an outlet 18 to a pump (not shown), which is used to extract the residual process gas, reactive agent and by-products from the assembly 100. Conditioning bars 2 are provided external to lips 15 to minimalise the ingress of air from the atmosphere into the extractor unit 9. Conditioning bars 2 are either lip seals touching substrate 1 or, dependent on the substrate being treated, anti-static bars, as used in the plastic film industry, which remove static from the surface of the substrate using high static potential and optionally use air jets to remove dust particulates. The conditioning bars as seen in FIG. 1 and 2 are antistatic carbon brushes.

In the present embodiment the atmospheric plasma generation unit 7 is fixed in place and a substrate 1 passes beneath the assembly on any form of conveying means (not shown) which may be varied to suit the substrate being treated in view of the fact that the conveyor does not form part of the assembly. The distance of the substrate from the tip 23 of each electrode 3, 4 is dependent on the substrate being treated, but typically, a short distance of a few millimetres will separate substrate 1 from tip 23.

In use, the assembly is placed adjacent to a non-conductive substrate 1, such that tip 23 of the electrodes 3, 4 and end 16 of lip 15 are a few millimetres from the surface of substrate 1. Substrate 1 in combination with extractor unit 8 forms a chamber around dielectric coated electrodes 3, 4. The chamber is adapted to substantially prevent the escape of residual process gas, reactive agent and by-products other than through channel 9 by way of the pump. A process gas is introduced into unit 7 through inlet 12 and an atomised liquid or powder is introduced into unit 7 through ultrasonic nozzle 10. The process gas and atomised liquid or powder are mixed together in unit 7 by effecting turbulence, the preferred options for causing turbulence are discussed below with respect to FIGS. 3 and 4. The only exit for the process gas/atomised liquid or powder mixture is through the plasma region formed by electrode spacer and dielectric coated electrodes 3, 4. When helium gas passes through plasma region 6 a plasma is affected when an appropriate potential difference is achieved between the dielectric coated electrodes 3, 4. The atomised liquid or solid is plasma treated to form active species which are then directed towards the substrate 1 through the plasma region 6 between dielectric coated electrodes 3, 4 and thereby interact with said substrate which is also in the plasma region as discussed above. Residual helium gas reactive agent and any by-products are then drawn under the tip 23 of the electrodes, up into channel 9, and are extracted through outlet 18.

In FIG. 2, there is provided an identical assembly to that described above in relation to FIG. 1 other than the electrodes. The assembly shown in FIG. 2 is intended in particular for electrically conducting substrates such as metals but may be used for non-conducting substrates. In this three electrode arrangement there is provided a central electrode 34 which is encased in a dielectric 33. Either side of this encased electrode 33, 34 are two grounded electrodes 37 which are provided in order to ensure that shorting between the base of the encased electrode 38 and substrate 1 is avoided. In this arrangement the central electrode 33, 34 is suspended in the gap between grounded electrodes 37 by means of a dual slit electrode spacer and the distance between dielectric base 38 of the encased electrode 33, 34 and the substrate 1 must be greater than the distance between the dielectric and the grounded electrodes 37 to ensure the avoidance of arcing between the encased electrode 33, 34 and the surface of substrate 1.

In use, therefore plasma is generated in plasma region 36 between the encased electrode 33, 34 and each grounded electrode 37 through which the process gas and reactive agents pass before being transferred into the extractor unit 8 through channel 9.

FIGS. 4a and 4b indicate two alternative ways of entry a liquid and/or solid coating-forming material (reactive agent) and process gas into unit 7 and the means of ensuring even distribution of the atornised spray prior to the mixture passing through plasma regions 6 or 36 dependent on the electrode assembly in use.

In FIG. 4a ultrasonic nozzle 10 has a frequency generating cable 13 and an air inlet 14 (air may be used as a carrier gas for the atomised liquid and/or solid coating-forming material). Process gas is introduced perpendicular to the main axis of body 7 by way of inlet 12 such that turbulence is generated close to the outlet of nozzle 10 as the gas flow reorientates to the main flow axis. This mixing process is best suited for higher process gas flow rates that may be used with low cost process gases such as air or nitrogen. In FIG. 4b ultrasonic nozzle 10 is mounted on the end of body 7 such that it lies along the main axis thereof and carrier gas is introduced by way of inlet 12 into body 7.

FIGS. 3 and 5 show a further alternative means of ensuring even distribution of process gas/liquid and/or solid coating-forming material. This is achieved by inducing turbulence with a restrictive disc 11 in the field of flow of the process gas immediately before the nozzle tip 20. Turbulence will be present within 6 disc diameters (when the disc has a diameter which is half that of the body 7 diameter. ½ pipe diameters downstream of the disc 11, so ensuring homogeneity of the liquid spray.

FIG. 6 shows a further means by which air can be introduced into the body 7 if needed to be used as the process gas in that a variable speed fan 40 is used to draw air into the body 7 and effect turbulence so as to cause mixing between incoming air and atomised liquid or powder introduced into body 7 by means of ultrasonic nozzle 10.

In FIG. 7 there is provided an assembly of the type shown in FIG. 2 which has been positioned near the narrowed exit 48 of a powder chute 50. A fluidisation gas is introduced into the chute at inlets 52 directed into the powder to assist in the mobility thereof. Because of the narrowing towards the exit 48, the obstruction caused by the assembly 100 and the high speed of the process gas/atomised liquid or solid coating material mixture leaving assembly 100, a venturi effect is caused by the process gas/atomised liquid or solid coating material mixture exiting from the plasma assembly 100, resulting in the entrainment of the powder/gas leaving the powder chute 50, such that the powder particles entering the atmospheric pressure plasma discharge and/or an ionised gas stream resulting therefrom are coated with the atomised liquid or solid coating forming material produced in assembly 100 of the invention. Any suitable means for collecting the plasma treated powder may be utilised.

1. An atmospheric plasma generation assembly (100) having an atmospheric plasma generation unit (7) with a body (17) containing a reactive agent introducing means (10), a process gas introducing means (12) and one or more multiple parallel electrode arrangements (4) adapted for generating a plasma, each arrangement having at least one partially dielectric coated electrode (3, 4), said assembly being adapted such that the only means of exit for a process gas and reactive agent introduced into said assembly is through the plasma region (6) between the electrodes (3, 4) said assembly (100) being adapted to move relative to a substrate substantially adjacent to the electrodes (3,4) outermost tips (23), characterized in that the reactive agent introducing means (10) is an atomizer for atomizing and introducing a reactive agent in the form selected from the group consisting of
(i) a liquid and
(ii) a solid
coating-forming material.

2. An assembly in accordance with claim 1 wherein the multiple parallel electrode arrangement (3, 4) comprises one or more pairs of at least partially dielectric coated and parallel electrodes (3, 4), situated a predetermined distance apart.

3. An assembly in accordance with claim 1 wherein the multiple parallel electrode arrangement comprises a three parallel electrode system (33, 34, 37) whereby a central electrode (34) is at least partially dielectric coated (33) and the other two electrodes (37) are earthed and situated one on each side of the central electrode (34) at a predetermined distance therefrom.

4. An assembly in accordance with claim 1 wherein the atmospheric plasma generation assembly body (17) is between 0.5 and 5 metres in length.

5. An assembly in accordance with claim 1 wherein there is provided an extractor unit (8) surrounding the atmospheric plasma generation unit (7), which is adapted to isolate the atmospheric plasma generation unit (7) from external atmosphere said extractor unit (8) comprising a means of removing exhaust process gas, reactive agents and by-products and said extractor body being shaped so as to comprise an open channel (9), such that in use edges of which are shaped to form a chamber around the electrodes (3,4) in combination with the substrate (1) and thereby substantially form a seal against the atmosphere, through which chamber exhaust process gas, reactive agents and byproducts are extracted.

6. An assembly in accordance with claim 1 wherein the atomizer (10) is an ultrasonic nozzle.

7. An assembly in accordance with claim 1 wherein the process gas inlet (12) is situated perpendicular to the axis of the atmospheric plasma generation assembly body (17) and opposite or perpendicular to the atomizer (10) in said atmospheric plasma generation assembly body (17) such that turbulence is generated close to the atomizer outlet as process gas flow is reoriented to the main direction of flow along the length of the axis of the atmospheric plasma generation assembly body (17).

8. An assembly in accordance with claim 5 wherein a restrictive disc (11) is positioned in the field of flow of the process gas.

9. An assembly in accordance with claim 1 wherein process gas, reactive agent and any by-products extracted through the extractor unit (8) act as an assembly (100) coolant.

10. An assembly in accordance with claim 1, which additionally comprises one or more conditioning bars (2).

11. An assembly in accordance with claim 10 wherein the conditioning bars (2) are selected from carbon brushes and electrostatic barrier guns.

12. An atmospheric plasma assembly in accordance with claim 1 which is adapted to move relative to a substrate substantially adjacent to the outermost tips 23 of the electrodes (3,4), such that the atmospheric plasma treatment of the substrate surface is carried out downstream of said electrodes (3,4).

13. An assembly in accordance with claim 1 wherein the substrate (1) is arranged to form a wall of the assembly (100) in which the plasma is generated and said wall is utilized to prevent release of process gas, reactive agents and by-products subsequent to plasma activation.

14. An assembly in accordance with claim 13 wherein the utilization of the substrate (1) as an assembly wall causes plasma treatment to be is restricted to one side of the substrate (1).

15. A method of treating a surface of a substrate with an assembly in accordance with claim 1 comprising:- introducing a process gas and an atomized liquid and/or solid coating-forming material into the atmospheric plasma generation assembly body (17), affecting a plasma, plasma treating the atomized liquid and/or solid coating-forming material and treating the surface of a substrate (1) with the resulting activated species generated thereby.

16. An atmospheric plasma generation assembly (100) adapted to be used for coating a substrate having an atmospheric plasma generation unit (7) with a body (17) containing a reactive agent introducing means (10), a process gas introducing means (12) and one or more multiple parallel electrode arrangements (4) adapted for generating a plasma, each arrangement having at least one partially dielectric coated electrode (3, 4), said assembly being adapted such that the only means of exit for a process gas and reactive agent introduced into said assembly is through the plasma region (6) between the aforementioned electrodes (3,4), characterized in that the reactive agent introducing means (10) is an atomizer for atomizing and introducing a reactive agent in the form of a liquid and/or solid coating-forming material.

17. An atmospheric plasma generation assembly in accordance with claim 16 wherein the substrate to be coated is a powder.

18. A method of treating a powdered substrate in the assembly of claim 16.

19. Use of an assembly in accordance with claim 2 for treating electrically non-conductive substrates.

20. Use of an assembly in accordance with claim 3 for treating electrically conductive substrates.

21. A method in accordance with claim 15 wherein the treatment of the substrate surface (1) is carried out downstream of the electrodes (3,4).

22. A method in accordance with claim 15 wherein process gas is an inert gas or inert gas based mixture.

23. A method in accordance with claim 22 wherein the process gas is utilized in combination with gaseous reactive agents.

24. A method in accordance with claim 23 wherein the gaseous reactive agents are oxidizing or reducing gaseous reactive agents in a mixture comprising 90 to 99% noble gas and 1 to 10% oxidizing or reducing gas.

25. A method in accordance with claim 15 wherein the atmospheric plasma generation assembly (100) pretreats the substrate.

26. A method in accordance with claim 15 wherein an atmospheric plasma generation assembly (100) is used to post treat the substrate.

27. A method in accordance with claim 15 wherein a gaseous reactive agent is additionally utilized.

28. A method in accordance with claim 15 wherein the substrate is pretreated by He cleaning/activation of substrate, followed by deposition of SiOₓ from a polydimethylsiloxane precursor in a first plasma region and further helium plasma treatment is utilized to provide extra cross-linking of the SiOₓ layer and finally a further coating is applied using a perfluorinated precursor.

29. An assembly in accordance with claim 6 wherein a restrictive disc (11) is positioned in the field of the flow of the process gas.
